(19) United States
(12) Patent Application Publication
(10) Pub. No.: US 2020/0132772 A1
(43) Pub. Date: Apr. 30, 2020

(54) DYNAMIC STATE ESTIMATION OF AN OPERATIONAL STATE OF A GENERATOR IN A POWER SYSTEM

(71) Applicant: Imperial College Innovations Limited, London (GB)

(72) Inventors: Abhinav SINGH, London (GB); Bikash PAL, London (GB)

(73) Assignee: Imperial College Innovations Limited, London (GB)

(21) Appl. No.: 16/631,779

(22) PCT Filed: Jul. 18, 2018
(86) PCT No.: PCT/GB2018/052032

§ 371 Date: Jan. 16, 2020

(30) Foreign Application Priority Data
Jul. 19, 2017 (GB) 1711587.4

(51) Int. Cl. G01R 31/34; H02J 3/24

(52) U.S. Cl. CPC G01R 31/343; H02J 2203/20; H02J 3/24

(57) ABSTRACT

Example embodiments described herein are directed towards dynamic state estimation of an operating state of a generator in a power system. Such estimation is performed for an individual generator in real time with improved accuracy and without the use of Global Position System (GPS) synchronization.

Example embodiments described herein are directed towards dynamic state estimation of an operating state of a generator in a power system. Such estimation is performed for an individual generator in real time with the use of calculated variances, thereby providing improved estimation accuracy. According to some embodiments, the estimation may utilize the calculation of a relative angle of an individual generator thereby providing estimation without the use of Global Position System (GPS) synchronization.

### BACKGROUND

A disturbance in a power system (such as a fault) can initiate spontaneous oscillations in the power-flows in transmission lines. These oscillations grow in magnitude within few seconds if they are undamped or poorly damped. This may lead to loss in synchronism of generators or voltage collapse, ultimately resulting in wide-scale blackouts. The power blackout of Aug. 10, 1996 in the Western Electricity Co-ordination Council region is a famous example of blackouts caused by such oscillations.

A generator's voltage, current and power are sinusoidal quantities, and since each sinusoid has a magnitude and a phase (which are together known as a phasor), these quantities can either be represented as sine waves, or as phasors. The conversion of sine waves to phasors is done by phasor measurement units (PMUs). In order to estimate the rotor angle any Dynamic State Estimation (DSE) algorithm available in modern power systems typically utilize synchronized measurements obtained using PMUs.

### SUMMARY

One problem with current state estimation methods is the level of error in the estimations. A further problem with current state estimation is time synchronization is that it has associated noise and synchronization-errors. Synchronization errors increase the total vector error (TVE) of PMU measurements. As synchronized measurements are used for DSE, these errors can get propagated to the estimated states and deteriorate the overall accuracy and robustness of estimation. It is also not possible to completely eliminate time synchronization as it is inherently required for estimation of rotor angles.

Example embodiments directed herein provide for more accurate estimations as a greater number of inputs and measurements, as well as variances for such inputs and measures, are used in the estimation. Furthermore, some of the example embodiments presented herein provide for a means of decentralized DSE where the need for time synchronization may be eliminated.

Accordingly, the example embodiments presented herein are directed towards an apparatus, computer readable medium and corresponding method for Dynamic State Estimation (DSE) of an operational state of a generator in a power system. The apparatus comprises a transceiver to receive measured voltage and current analog signals associated with the generator. The apparatus further comprises a processor to sample the received measured signals to voltage and current discrete signals. The processor is further to estimate magnitude, phase and frequency variables of the voltage and current, as well as associated voltage and current variances, respectively, for each variable, using the discrete voltage and current signals as an input in a Discrete Fourier Transform (DFT). The processor is also to calculate a power variable and associated power variance based on the estimated magnitude, phase and frequency variables for the voltage and current, as well as associated voltage and current variances for each variable. The processor is further to estimate the dynamic state of the generator using at least a subset of the estimated magnitude, phase and frequency variables of the voltage and current, as well as associated voltage and current variances for each variable, and the calculated power variable and the associate power variance using a state estimator.

The example embodiments described herein provide a means of DSE with improved accuracy as a greater number of measurements and inputs are used in conjunction with the DFT and state estimator. Furthermore, the example embodiments presented herein improve the accuracy of such estimates with the use of calculated variances.

According to some of the example embodiments, the estimation of the dynamic state of the generator may further comprise estimating a relative angle as a difference between a rotor angle and an estimated voltage phase. The processor may provide such estimation.

According to some of the example embodiments, with the use of the estimation of a relative angle, time synchronization is not needed. Therefore, DSE may be provided in a decentralized manner where the dynamic states may be utilized for decentralized control of a particular generator.

### BRIEF DESCRIPTION OF THE DRAWINGS

The foregoing will be apparent from the following more particular description of the examples provided herein, as illustrated in the accompanying drawings in which like reference characters refer to the same parts throughout the different views. The drawings are not necessarily to scale, emphasis instead being placed upon illustrating the examples provided herein:

FIG. 1 is an illustration of a working example featuring a 16-machine, 68-bus power system model, according to some of the example embodiments described herein;

FIG. 2 is a graphical comparison of DSE for α¹³, ω¹³, and E_{q}′¹³ for a base case, according to some of the example embodiments presented herein;

FIG. 3 is a graphical comparison of estimation errors for α¹³, ω¹³, and E_{q}′¹³ for the base case, according to some of the example embodiments presented herein;

FIG. 4 is a graphical comparison of DSE for E_{d}′¹³, ψ_{2q}¹³, ψ_{1d}¹³ and Vᵣ¹³ for the base case, according to some of the example embodiments presented herein;

FIG. 5 is a graphical comparison of estimation errors for E_{d}′¹³, ψ_{2q}¹³, ψ_{1d}¹³ and Vᵣ¹³ for the base case, according to some of the example embodiments presented herein;

FIG. 6 is a graphical comparison of DSE for ω¹³ for varying noise levels, according to some of the example embodiments presented herein;

FIG. 7 are tables featuring root mean square errors for DSE and DSE with PMU, according to some of the example embodiments;

FIG. 8 is an operational node diagram of an apparatus for DSE of a generator, according to some of the example embodiments presented herein;

FIG. 9 is an example node configuration of the apparatus described in FIG. 8, according to some of the example embodiments described herein; and

FIG. 10 is a flow diagram depicting example operations which may be taken by the apparatus of FIGS. 8 and 9, according to some of the example embodiments described herein.

### NOMENCLATURE

The following sections provides a listing of the mathematical nomenclature, and their corresponding meaning, as used throughout this document:

α difference of rotor angle and stator voltage phase in rad
0 denotes a zero matrix (or vector) of appropriate size
χ denotes a state sigma point
γ denotes a measurement sigma point
g, g̅ discrete and continuous forms of differential functions, respectively
h a column vector of the system algebraic functions
I denotes an identity matrix of appropriate size
K the Kalman gain matrix
P denotes a covariance matrix or cross-covariance matrix
u′, v column vectors of pseudo-inputs and process noise, respectively
w′, w column vectors of noise in y and u′, respectively
x, y column vectors of states and measurements, respectively
X composite state vector
δ rotor angle in rad
\hat{ }, denote estimated and predicted values, respectively
λ denotes the λ^{th} component of a DFT
ω, ω₀ rotor-speed and its synchronous value in rad/s, respectively
Ψ_{1d} sub-transient emfs due to d axis damper coil in p.u.
Ψ_{2q} sub-transient emfs due to q axis damper coil in p.u.
σ denotes standard deviation, with σ² as variance
σ phase of Y's fundamental component in rad
θ_{V}, θ_{I} phases of stator voltage and current, respectively, in rad
D rotor damping constant in p.u.
E′_{d} transient emf due to flux in q-axis damper coil in p.u.
E′_{q} transient emf due to field flux linkages in p.u.
E′_{fd} field excitation voltage in p.u.
f frequency of Y's fundamental component in Hz
fₛ sampling frequency for interpolated-DFT method in Hz
f_{V}, f₀ frequency of V in p.u. and its base value in Hz, respectively
H generator inertia constant in s
h Hann window function
I, Iₘ analogue stator current and its magnitude, respectively, in p.u.
i, j denote the i^{th} generation unit and \sqrt{−1}, respectively
I_{d}, I_{q} d-axis and q-axis stator currents, respectively, in p.u.
k, k̅,l k^{th} and (k−1)th samples and the l^{th} sigma-point, respectively
Kₐ AVR gain in p.u.
K_{d1} the ratio (X″_{d}−Xₗ)/(X_{d}′−Xₗ)
K_{d2} the ratio (X_{d}′−X″_{d})/(X_{d}′−Xₗ)
K_{q1} the ratio (X_{q}″−Xₗ)/(X_{q}′−Xₗ)
K_{q2} the ratio (X_{q}′−X″_{q})/(X_{q}′−Xₗ)
m, n number of states in x and X, respectively, (n=m+2)
N, M total samples for finding DFT and total generation units, respectively
Pₑ active electrical-power output of a machine in p.u.
Rₛ armature resistance in p.u.
t system time in s
T, T₀ denote transpose and UKF's sampling period (in s), respectively
Tₑ, Tₘ₀ electrical and mechanical torques, respectively, in p.u.
Tᵣ time constant for the AVR filter in s
T_{d0}′, T_{q0}′ d-axis and q-axis transient time constants, respectively, in s
T_{d0}″, T_{q0}″ d-axis and q-axis sub-transient time constants, respectively, in s
V, Vₘ analogue stator voltage and its magnitude, respectively, in p.u.
V_{d}, V_{q} d-axis and q-axis stator voltages, respectively, in p.u.
Vᵣ, V_{ref} AVR-filter voltage and AVR-reference voltage, respectively, in p.u.
W DFT of Hann window function
X_{d}, X_{q} d-axis and q-axis synchronous reactances, respectively, in p.u.
X_{d0}′, X_{q0}′ d-axis and q-axis transient reactances, respectively, in p.u.
X_{d0}″, X_{q0}″ d-axis and q-axis sub-transient reactances, respectively, in p.u.
Xₗ armature leakage reactance in p.u.
Y denotes a sinusoidal signal with harmonics and noise
Yₘ magnitude of Y's fundamental component in p.u.
Z DFT of the product of Y and h

### DETAILED DESCRIPTION

In the following description, for the purposes of explanation and not limitation, specific details are set forth, such as particular components, elements, techniques, etc. in order to provide a thorough understanding of the examples provided herein. However, the examples may be practiced in other manners that depart from these specific details. In other instances, detailed descriptions of well-known methods and elements are omitted so as not to obscure the description of the examples provided herein.

Example embodiments described herein are directed towards dynamic state estimation of an operating state of a generator in a power system. A disturbance in a power system (such as a fault) can initiate spontaneous oscillations in the power-flows in transmission lines. In order to monitor and control such oscillations and related dynamics which cause instability, the operating state of the system needs to be estimated in real-time, with update rates which are in time scales of ten milliseconds or less (as the time constants associated with such oscillations are not more than ten milliseconds), and this real-time estimation of operating state is known as dynamic state estimation (DSE).

The dynamic states which are estimated and obtained as outputs from DSE algorithms are angles, speeds, voltages and fluxes of the rotors of all the generators in the power system. The inputs which are given to DSE algorithms are some measurable time-varying quantities such as voltage and current of the stator, and some measurable time-invariant quantities such as resistances, reactances, inertia and other constants for the generator. The constant quantities are measured beforehand, and are used as parameters in DSE algorithms.

A generator's voltage, current and power are sinusoidal quantities, and since each sinusoid has a magnitude and a phase (which are together known as a phasor), these quantities can either be represented as sine waves, or as phasors. The conversion of sine waves to phasors is done by phasor measurement units (PMUs). In order to estimate the rotor angle any Dynamic State Estimation (DSE) algorithm available in power system current systems typically utilize synchronized measurements obtained using PMUs.

Example embodiments presented herein provide a means of improved DSE where greater number of inputs and measurements, as well as variances for such inputs and measurements, are utilized in the estimation. Thus, providing improved accuracy for the measurements. According to some of the example embodiments, a means for DSE is provided without the use of time synchronization.

One problem with time synchronization is that it has associated noise and synchronization-errors. Synchronization errors increase the total vector error (TVE) of PMU measurements. As synchronized measurements are used for DSE, these errors can get propagated to the estimated states and deteriorate the overall accuracy and robustness of estimation. It is also not possible to completely eliminate time synchronization as it is inherently required for estimation of rotor angles.

According to some of the example embodiments, it has been appreciated that although time synchronization is typically used for the estimation of the rotor angle, it is not needed for estimation of other dynamic states, such as rotor speed, rotor voltages and fluxes, as these states are not defined with respect to a common reference angle. Thus, if the dynamic model which is used for estimation can be modified in such a way that rotor angle is replaced with another angle which does not require time-synchronization, then this can minimize the effects of synchronization on accuracy and robustness of estimation.

Some of the example embodiments provide an algorithm for DSE which realizes the above concept. This is done by modifying the estimation model to estimate a relative angle (which does not require synchronization) instead of rotor angle. One such angle is the difference between the rotor angle and the generator terminal voltage phase, also known as the internal angle of the generator. As the rotor angle and the voltage phase have a common reference angle, this reference angle gets cancelled in the difference of the two quantities. Thus, the internal angle, rotor speed, voltages and fluxes can be estimated using the modified estimation model without requiring any synchronized measurements. These dynamic states can then be utilized for decentralized control of the generator. It should be noted that, according to some of the example embodiments, if the estimation of rotor angle is specifically required then it can be indirectly estimated as the sum of the estimated internal angle and the measured terminal voltage phase obtained using PMU.

An example advantage of some of the example embodiments provided herein is to provide a system and method of DSE in which dynamic states are estimated without any time synchronization by incorporating internal angle in estimation model, which in turn ensures robustness of the method to synchronization errors.

The error in phasor measurements considered in several existing methods of DSE is much less than 1% TVE. Such methods of DSE do not consider realistic errors in measurements. The example embodiments presented herein considers and remains accurate for varying levels of errors in measurements—from 0.1% to 10%. Furthermore, none of the currently available methods take into account GPS synchronization errors.

As synchronization is not required for estimation of the states, according to some of the example embodiments, DSE for these states can be performed using the analogue measurements directly acquired from current transformers (CTs) and voltage transformers (VTs). This is particularly beneficial for decentralized control purposes.

According to some of the example embodiments, a dual-stage estimation process has been proposed in which a Discrete Fourier transform (DFT) and a state estimator. According to some of the example embodiments, the DFT may be an interpolated DFT and the state estimator may be an unscented Kalman filtering (UKF). According to some of the example embodiments the DFT and the state estimator have been combined as two stages of estimation. The DFT stage dynamically provides estimates of means and variances of the inputs required by the state estimation stage, and this continuous updating of variances may provide noise-robustness of the proposed example embodiments. In existing methods of DSE for power systems, only static estimates of measurement variances are provided to the estimator.

According to some of the example embodiments, analytical expressions have been obtained for the means and variances of the parameter estimates of a sinusoidal signal (which are given as input to the state estimation stage from the DFT stage). Most of these expressions are currently not available in literature.

Rest of the description is organized as follows. First, decoupled equations which may be utilized in conjunction with the example embodiments presented herein are discussed under the subheading ‘Power System Dynamics in a Decoupled Form’. Thereafter, the process for estimation of magnitude, phase and frequency of the analogue signals of terminal voltage and current is discussed under the subheading ‘DFT based Estimation’. An explanation as to how these estimates may be further used for DSE using a state estimator is provided under the subheading ‘State Estimation’. A working example featuring simulations to demonstrate the development of the example embodiments presented herein is provided under the subheading ‘Case Study’. An example node configuration of an apparatus that may be utilized in providing DSE is discussed under the subheading ‘Example Node Configuration’. Finally, an operational flow is provided under the ‘Example Operations’.

Power System Dynamics in a Decoupled Form

A power system comprises a wide variety of elements, including generators, their controllers, transmission lines, transformers, relays and loads. All these elements are electrically coupled to each other, and, therefore, in order to define a power system using dynamic mathematical equations, knowledge of the models, states and parameters of all these constituent elements is useful. Acquiring this knowledge in real-time is not feasible as power systems span wide geographic regions, which are as large as a country, or even a continent. Therefore, according to some of the example embodiments, dynamic equations of the power system in a decoupled form is utilized, so that the real-time estimation of dynamic states can be conducted. According to some of the example embodiments, the estimation may be performed in a decentralized manner.

Such a decoupling of system equations may be achieved if a generator and its controller(s) is considered as a decentralized unit, and the stator terminal voltage magnitude, Vm, and its phase, θV, are treated as ‘inputs’ in the dynamic equations, instead of considering them as algebraic quantities or measurements. This concept is referred to herein as ‘pseudo-inputs’ for decoupling the equations.

In order to estimate the internal angle, which is the difference between the rotor angle and the voltage phase, instead of estimating the rotor angle, the decoupled equations and the pseudo-inputs for a generator are altered. The altered decoupled equations are given by equations (1)-(11), derived using the sub-transient model of machines with four rotor coils in each machine, known as IEEE Model 2.2 as provided in “IEEE Guide for Synchronous Generator Modeling Practices and Applications in Power System Stability Analyses,” IEEE Std 1110-2002 (Revision of IEEE Std 1110-1991), pp. 1-72, 2003. In these equations, the altered pseudo-inputs are Vm and voltage frequency, fV, and i refers to the system's ith machine or generator, 1≤i≤M. Slow dynamics of the speed-governor have been ignored in this model (although they can also be added, if required). Also, model of a static automatic voltage regulator (AVR) is included with the model of each machine.

$$\begin{matrix}Δ {\dot{α}}^{i} = ( {ω}^{i} - {f}_{V}^{i} ) & ( 1 ) \\ Δ {\dot{ω}}^{i} = \frac{{ω}_{0}}{2 {H}^{i}} ( {T}_{m 0}^{i} - {T}_{e}^{i} ) - \frac{{D}^{i}}{2 {H}^{i}} Δ {ω}^{i} & ( 2 ) \\ {\dot{E}}_{d}^{′ i} = \frac{1}{{T}_{q o}^{′i}} [ - {E}_{d}^{′ i} - ( {X}_{q}^{i} - {X}_{q}^{′ i} ) [ {K}_{q 1}^{i} {I}_{q}^{i} + {K}_{q 2}^{i} \frac{{Ψ}_{2 q}^{i} + {E}_{d}^{′ i}}{{X}_{q}^{′ i} - {X}_{l}^{i}} ] ] & ( 3 ) \\ {\dot{E}}_{d}^{′} = \frac{{E}_{fd}^{i} - {E}_{q}^{′i} + ( {X}_{d}^{i} - {X}_{d}^{′i} ) [ {K}_{d 1}^{i} {I}_{d}^{i} + {K}_{d 2}^{i} \frac{{Ψ}_{2 q}^{i} + {E}_{d}^{′ i}}{{X}_{q}^{′ i} - {X}_{l}^{i}} ]}{{T}_{q o}^{′ i}} & ( 4 ) \\ {\dot{Ψ}}_{1 d}^{i} = \frac{1}{{T}_{do}^{″ i}} [ {E}_{q}^{′i} + ( {X}_{q 1}^{′i} - {X}_{l}^{ i} ) {I}_{d}^{i} - {Ψ}_{1 d}^{i} ] & ( 5 ) \\ {Ψ}_{2 q}^{i} = \frac{1}{{T}_{qo}^{″i}} [ - {E}_{d}^{′ i} + ( {X}_{q}^{′ i} - {X}_{l}^{i} ) {I}_{q}^{i} - {Ψ}_{2 q}^{i} ] & ( 6 ) \\ {\dot{V}}_{r}^{i} = \frac{1}{{T}_{r}^{i}} [ {V}_{m}^{i} - {V}_{r}^{i} ] , \\ where , & ( 7 ) \\ {E}_{fd}^{i} = {K}_{a}^{i} [ {V}_{ref}^{i} - {V}_{r}^{i} ] , \\ {E}_{fdmin}^{i} \leq {E}_{fd}^{i} \leq {E}_{fdmax}^{i} & ( 8 ) \\ [ \begin{matrix}{I}_{d}^{i} \\ {I}_{q}^{i}\end{matrix} ] = {[ \begin{matrix}{R}_{s}^{i} & {X}_{q}^{″ i} \\ - {X}_{d}^{″ i} & {R}_{s}^{i}\end{matrix} ]}^{- 1} [ \begin{matrix}{E}_{d}^{′ i} {K}_{q 1}^{i} - {Ψ}_{2 q}^{i} {K}_{q 2}^{i} - {V}_{d}^{i} \\ {E}_{q}^{′ i} {K}_{d 1}^{i} - {Ψ}_{1 d}^{i} {K}_{d 2}^{i} - {V}_{q}^{i}\end{matrix} ] & ( 9 ) \\ {T}_{e}^{i} = \frac{{ω}_{0}}{{ω}^{i}} {P}_{e}^{i} , \\ {P}_{e}^{i} = {V}_{d}^{i} {I}_{d}^{i} + {V}_{q}^{i} {I}_{q}^{i} = {V}_{m}^{i} {I}_{m}^{i} cos ( {θ}_{V}^{i} - {θ}_{I}^{i} ) & ( 10 ) \\ {I}_{m}^{i} = \sqrt{{I}_{d}^{{i}^{2}} + {{I}_{q}^{i}}^{2}} , \\ {V}_{d}^{i} = - {V}_{m}^{i} sin {a}^{i} , \\ {V}_{q}^{i} = {V}_{m}^{i} cos {α}^{i} & ( 11 )\end{matrix}$$

The above equations may be written in the following composite state-space form which may be used for DSE (here pseudo-inputs are denoted by u′ᵢ, and the process noise and the noise in pseudo inputs have been included, and denoted by vⁱ and ω′ⁱ, respectively).

\dot{x}ⁱ=g′ⁱ(xⁱ,u′ⁱ,w′ⁱ)+vⁱ;u′ⁱ−w′ⁱ=[Vₘⁱ f_{V}ⁱ]^{T}

xⁱ=[αⁱωⁱ E′_{d}ⁱ E′_{q}ⁱΨ_{1d}ⁱΨ_{2q}ⁱ Vᵣⁱ]^{T} (12)

DFT Based Estimation

The example embodiments described herein make use of an interpolated DFT for estimating the parameters of a sinusoidal signal. It should be appreciated that other forms of DFTs may be utilized in the estimation of the parameters. The use of an interpolated DFT based estimation has the example advantage of being both fast and accurate enough for real-time control applications in power systems. According to some of the example embodiments, the DFT may be used for finding the estimates of frequency, magnitude and phase of the fundamental components of measurements obtained from CTs and PTs.

The fundamental component of a sinusoidal signal can be extracted by multiplying the signal with a suitable window function which eliminates other harmonics and higher frequency components in the signal, followed by finding its DFT. One such function is, for example, a Hanning window function given by hk=sin 2(πk/N), and if this function is multiplied with N samples of an analogue signal Y(t) sampled at a frequency fs, then DFT of the product is given by Z(λ) as follows.

$$Z ( λ ) = {\sum }_{k = 0}^{N - 1} {Y}_{k} {h}_{k} {e}^{- \frac{j 2 π k λ}{N}} = \frac{{Y}_{m}}{2 j} {e}^{j θ} W ( λ - \frac{f N}{{f}_{s}} ) - \frac{{Y}_{m}}{2 j} {e}^{j θ} W ( λ - \frac{f N}{{f}_{s}} ) - \frac{{Y}_{m}}{2 j} {e}^{- j θ} W ( λ + \frac{fN}{{f}_{s}} ) \qquad ( 13 )$$

where, Ym, θ and f are magnitude, phase and frequency of Y's fundamental component, respectively; λ∈{0, 1, . . . , N−1}; and W(λ) is the following DFT of Hanning window function.

$$W ( λ ) = {\sum }_{k = 0}^{N - 1} {h}_{k} {e}^{- \frac{j 2 π k λ}{N}} = {\sum }_{k = 0}^{N - 1} {sin}^{2} ( \frac{π k}{N} ) {e}^{- \frac{j 2 π k λ}{N}} \qquad ( 14 )$$

A concept in interpolated-DFT based estimation is to approximate W(λ) with the following expression, provided that N>>1 and λ<<N.

$$W ( λ ) \approx \frac{N}{4 π j} \frac{( 1 - {e}^{- j 2 π λ} )}{( λ - {λ}^{3} )} \qquad ( 15 )$$

By substituting equation (15) in equation (13), Z(λ) can be expressed as follows for N>>1 and λ<<N.

$${Z}_{λ} = Z ( λ ) = \frac{{\hat{Y}}_{m} N}{8 π} [ \frac{{e}^{j \hat{θ}} ( {e}^{- j 2 π ( λ - \frac{\hat{f} N}{{f}_{s}} )} - 1 )}{( λ - \frac{\hat{f} N}{{f}_{s}} ) - {( λ - \frac{\hat{f} N}{{f}_{s}} )}^{3}} - \frac{{e}^{j \hat{θ} ( {e}^{- j 2 π ( λ + \frac{\hat{f} N}{{f}_{s}} )} - 1 )}}{( λ + \frac{\hat{f} N}{{f}_{s}} ) - {( λ + \frac{\hat{f} N}{{f}_{s}} )}^{3}} ] \qquad ( 16 )$$

where Ŷₘ, \hat{θ} and \hat{f} denote the estimates of Yₘ, θ and f, respectively. As equation (16) has three unknowns (which are Ŷₘ, \hat{θ} and \hat{f}), three distinct equations are required to estimate these unknowns. This may be done by choosing any three distinct values of λ in equation (16) (say λ=1, λ=2 and λ=3). The obtained values of Ŷₘ, \hat{θ} and \hat{f} will have associated estimation errors which will depend on N and on the values of λ which are used for generating the three distinct equations. More precisely, these estimation errors are inversely proportional to N⁴, and, hence, N should be as large as practically feasible. In the example embodiments described herein N is taken to be in the order of 10³, as this is the highest order for N for which interpolated-DFT can run on a state-of-the-art DSP processor without overloading it, however it should be appreciated such values are presented herein merely as an example. Overloading refers to overall processor usage of above 95%. Also, for a given N, the estimation errors are minimized if the choices for λ are taken as λ=0, λ=1 and λ=2, provided that

$$\frac{\hat{f} N}{{f}_{s}} < 2.1 ;$$

otherwise, for

$$2.1 < \frac{\hat{f} N}{{f}_{s}} < 3 ,$$

the errors are minimized if the choices are λ=1, λ=2 and λ=3. The value of

$$\frac{\hat{f} N}{{f}_{s}}$$

should not be greater than 3 as then the delay in obtaining the estimated values becomes too large (that is, more than two cycles, or more than 0.04 s for a 50 Hz power system), and at the same time it should not be too small as then the accuracy of estimation is diminished. According to some of the example embodiments, an intermediate value of

$$\frac{\hat{f} N}{{f}_{s}} \approx 1.5$$

has been taken and, hence, the former choices of λ=0, λ=1 and λ=2 are applicable.

$$\frac{\hat{f} N}{{f}_{s}}$$

is an unknown quantity as f needs to be estimated. But because of power system operational requirements, f should remain within 5% of the base system frequency, f₀ (which is usually 50 Hz or 60 Hz), and, hence, if N and fₛ are chosen such that

$$\frac{{f}_{0} N}{{f}_{s}} = 1.5 , then \frac{\hat{f} N}{{f}_{s}} \approx 1.5 .$$

The 3 equations which are obtained by putting λ=0, λ=1 and λ=2 in equation (16) can be written in matrix form as follows.

$$[ \begin{matrix}\frac{\frac{\hat{f} N}{{f}_{s}} - 2}{\frac{\hat{f} N}{{f}_{s}} + 1} & \frac{\frac{\hat{f} N}{{f}_{s}} + 2}{\frac{\hat{f} N}{{f}_{s}} - 1} & {Z}_{0} \\ 1 & 1 & {Z}_{1} \\ \frac{\frac{\hat{f} N}{{f}_{s}}}{\frac{\hat{f} N}{{f}_{s}} - 3} & \frac{\frac{\hat{f} N}{{f}_{s}}}{\frac{\hat{f} N}{{f}_{s}} + 3} & {Z}_{2}\end{matrix} ] [ \begin{matrix}\frac{{\hat{Y}}_{m} N {e}^{j \hat{θ}} ( {e}^{\frac{j 2 π \hat{f} N}{{f}_{s}}} - 1 )}{8 π \frac{\hat{f} N}{{f}_{s}} ( \frac{\hat{f} N}{{f}_{s}} - 1 ) ( \frac{\hat{f} N}{{f}_{s}} - 2 )} \\ \frac{{\hat{Y}}_{m} N {e}^{- j \hat{θ}} ( {e}^{- \frac{j 2 π \hat{f} N}{{f}_{s}}} - 1 )}{8 π \frac{\hat{f} N}{{f}_{s}} ( \frac{\hat{f} N}{{f}_{s}} + 1 ) ( \frac{\hat{f} N}{{f}_{s}} + 2 )} \\ - 1\end{matrix} ] = [ \begin{matrix}0 \\ 0 \\ 0\end{matrix} ] \qquad ( 17 )$$

Equation (17) implies that the product of a square-matrix and a column vector is equal to a zero vector, when both the matrix and the vector have non-zero elements. This occurs if the columns of the matrix are linearly dependent, that is, the determinant of the matrix is zero, given as follows.

$$[ \begin{matrix}\frac{\hat{f} N - 2 {f}_{s}}{\hat{f} N + {f}_{s}} & \frac{\hat{f} N + 2 {f}_{s}}{\hat{f} N - {f}_{s}} & {Z}_{0} \\ 1 & 1 & {Z}_{1} \\ \frac{\hat{f} N}{\hat{f} N - 3 {f}_{s}} & \frac{\hat{f} N}{\hat{f} N + 3 {f}_{s}} & {Z}_{2}\end{matrix} ] = 0 \qquad ( 18 )$$

Simplification of the above determinant gives \hat{f} as follows.

$$\hat{f} = \frac{{f}_{s}}{N} \sqrt{\frac{{Z}_{0} + 2 {Z}_{1} + 9 {Z}_{2}}{{Z}_{0} - 2 {Z}_{1} + {Z}_{2}}} \qquad ( 19 )$$

\hat{θ} may be obtained by substituting the above value of \hat{f} back into equation (16) and eliminating Ŷₘ. To do this, the equation which is obtained by putting λ=0 in equation (16) is divided by the equation obtained by putting λ=1 in equation (16), which comes as follows.

$$\frac{{Z}_{0}}{{Z}_{1}} = \frac{{e}^{j \hat{θ}} B + {e}^{- j \hat{θ}} C}{{e}^{j \hat{θ}} E + {e}^{- j \hat{θ}} F} ; \\ B = \frac{1 - {e}^{\frac{j 2 π \hat{f} N}{{f}_{s}}}}{\frac{\hat{f} N}{{f}_{s}} - {[ \frac{\hat{f} N}{{f}_{s}} ]}^{3}} ; \\ C = \frac{1 - {e}^{- \frac{j 2 π \hat{f} N}{{f}_{s}}}}{\frac{\hat{f} N}{{f}_{s}} - {[ \frac{\hat{f} N}{{f}_{s}} ]}^{3}} ; \\ E = \frac{1 - {e}^{\frac{j 2 π \hat{f} N}{{f}_{s}}}}{\frac{\hat{f} N}{{f}_{s}} 1 - {[ \frac{\hat{f} N}{{f}_{s}} - 1 ]}^{3}} ; \\ F = \frac{1 - {e}^{- \frac{j 2 π \hat{f} N}{{f}_{s}}}}{\frac{\hat{f} N}{{f}_{s}} + 1 - {[ \frac{\hat{f} N}{{f}_{s}} + 1 ]}^{3}} \qquad ( 20 )$$

Solving for e^{j\hat{θ}} using equation (20) gives the following expression.

$${e}^{j \hat{θ}} = \sqrt{\frac{{Z}_{0} F - {Z}_{1} C}{{Z}_{1} B - {Z}_{0} E}} \hat{θ} = \frac{1}{2 j} ln \{ \frac{{Z}_{0} F - {Z}_{1} C}{{Z}_{1} B - {Z}_{0} E} \} \qquad ( 21 )$$

Using equations (21) and (16) (with λ=0), Ŷₘ comes as follows.

$${\hat{Y}}_{m} = \frac{8 π {Z}_{0}}{[ N \{ B {e}^{j \hat{ θ}} + C {e}^{- j \hat{θ}} \} ]} \qquad ( 22 )$$

where B, C, and e^{j\hat{θ}} are given by equations (20)-(21).

It should be noted that Ŷₘ, \hat{θ} and \hat{f} are real quantities, but they are obtained as functions of complex quantities (given in the right hand sides (RHSs) of equations (19), (21) and (22), respectively). Hence, these quantities will have negligible but finite imaginary parts associated with them because of finite computational accuracy of any computational device. Thus, during implementation, the imaginary parts should be ignored and only the real parts of RHSs should be assigned to Ŷₘ, \hat{θ} and \hat{f}. Also, as Ŷₘ and \hat{f} are strictly positive, absolute values of real parts of respective RHSs should be assigned to them.

The variance of the above estimate of \hat{f} in equation (19) is approximately twice the minimum possible variance which is theoretically achievable using any unbiased estimator (known as Cramer-Rao bound (CRB)). CRB for frequency estimation of a sinusoidal signal and is given by CRB(\hat{f}) (in Hz²) as follows.

$$CRB ( \hat{f} ) = {( \frac{{f}_{s}}{2 π} )}^{2} \frac{24 {σ}_{Y}^{2}}{{\hat{Y}}_{m}^{2} N ( {N}^{2} - 1 )} \qquad ( 23 )$$

where σ_{Y}² is the variance of noise in Y (in p.u.). CRBs for Ŷₘ and \hat{θ} are given by CRB(Ŷₘ) (in p.u.) and CRB(\hat{θ}) (in rad²), respectively, as follows.

$$CRB ( {\hat{Y}}_{m} ) = \frac{2 {σ}_{Y}^{2}}{N} ; \\ CRB ( \hat{θ} ) = \frac{4 {σ}_{Y}^{2} ( 2 N + 1 )}{{\hat{Y}}_{m}^{2} N ( N - 1 )} \qquad ( 24 )$$

The variances of Ŷₘ and \hat{θ} are found to be approximately two and six times the above CRBs in equation (24), respectively; and hence, the estimated variances of \hat{f}, \hat{θ} and Ŷₘ are given by \hat{σ}_{f}² (in p.u.), \hat{σ}_{Y}_{ₘ}² (in p.u.) and \hat{σ}_{θ}² (in rad²), respectively, as follows.

$${\hat{σ}}_{f}^{2} = \frac{2 CRB ( \hat{f} )}{{f}_{0}^{2}} ; \\ {\hat{σ}}_{{Y}_{m}}^{2} = 2 CRB ( {\hat{Y}}_{m} ) ; \\ {\hat{σ}}_{θ}^{2} = 6 CRB ( \hat{θ} ) \qquad ( 25 )$$

where CRB(\hat{f}), CRB(Ŷₘ) and CRB(\hat{θ}) are given by equations (23)-(24). Estimates of means and variances obtained above are given as inputs to the state estimation stage (e.g., UKF), as detailed in the next section.

An example advantage of obtaining the analytical expressions for \hat{σ}_{f}², \hat{σ}_{Y}_{ₘ}², and \hat{σ}_{θ}² in equations (23)-(25) is that these variances may be continuously updated and provided to the dynamic estimator (which is the state estimation stage, for example, the UKF stage) along with \hat{f}, \hat{θ} and Ŷₘ, thereby improving the accuracy of dynamic state estimation.

State Estimation

State estimation will be described herein using an UKF as an example. However, it should be appreciated that other forms of state estimation, or types of Kalman Filters, may be employed. UKF is a nonlinear method for obtaining dynamic state estimates of a system. It employs the idea that performing DSE is easier if the distribution of state estimates is transformed, than if the system model itself is transformed through linearization. System linearization requires computation of Jacobian matrices and is a mathematically challenging task for a high order power system model, especially if it needs to be done at every iteration. Since linearization is not required in UKF, and, moreover, it has higher accuracy and similar computational speeds as that of linear methods of DSE, UKF has been used for performing DSE according to some of the example embodiments, however, other Kalman Filters or forms of state estimation may also be employed. UKF is a discrete method and, hence, the system given by (12) may be discretized before UKF may be applied to it. Discretizing (12) at a sampling period T₀, by approximating \dot{x}ⁱ with (x^{ik}−x^{ik̅})/T₀, gives the following equation (where k and k̅ represent the kth and (k−1)^{th} samples, respectively).

x^{ik}=x^{ik̅}+T₀ǵ^{l}(x^{ik̅},ú^{ik̅},\acute{w}^{ik̅})+v^{ik̅}⇒x^{ik}=gⁱ(x^{ik̅},u^{ik̅},\acute{w}^{ik̅})+v^{ik̅} (26)

In the above model, \hat{V}ₘ^{ik} and \hat{f}_{V}^{ik} (found using the DFT method) are used in the pseudo-input vector ú^{ik} as follows.

ú^{ik}=[\hat{V}ₘ^{ik}\hat{f}_{V}^{ik}]^{T}=[Vₘ^{ik} f_{V}^{ik}]^{T}+\acute{w}^{ik} (27)

UKF also utilizes a measurement model besides the above process model. The estimates of active power, Pₑ^{ik} (defined by equation (10)), and stator current magnitude, Iₘ^{ik} (defined by equation (11)), which are obtained using the DFT method are used as measurements for UKF. After incorporating the measurement noise, w^{ik}, the measurement model is given as follows.

$${y}^{ik} = [ \begin{matrix}{\hat{P}}_{e}^{ik} \\ {\hat{I}}_{m}^{ik}\end{matrix} ] = [ \begin{matrix}{V}_{d}^{ik} {I}_{d}^{ik} + {V}_{q}^{ik} {I}_{q}^{ik} \\ \sqrt{{I}_{d}^{{ik}^{2}} + {I}_{q}^{{ik}^{2}}}\end{matrix} ] + {w}^{ik} ⇒ {y}^{ik} = {h}^{i} ( {x}^{ik} , {{u}^{′}}^{ik} , {{w}^{′}}^{ik} ) + {w}^{ik} \qquad ( 28 )$$

ú^{ik} and y^{ik} are estimated quantities and have finite variances which may be included in the process and measurement models, respectively. This may be done by including \acute{w}^{ik} and w^{ik} in the models as the following zero-mean noises.

$$\begin{matrix}{{w}^{′}}^{ik} = [ \begin{matrix}{{w}^{′}}_{{V}_{m}^{ik}} \\ {{w}^{′}}_{{f}_{V}^{ik}}\end{matrix} ] ; {{w}^{{\hat{}}^{′}}}^{ik} = [ \begin{matrix}0 \\ 0\end{matrix} ] ; {P}_{w}^{ik} = [ \begin{matrix}{\hat{σ}}_{{V}_{m}^{ik}}^{2} & 0 \\ 0 & {\hat{σ}}_{{f}_{v}^{ik}}^{2}\end{matrix} ] & ( 29 ) \\ {w}^{ik} = [ \begin{matrix}{W}_{{P}_{e}^{ik}} \\ {W}_{{I}_{m}^{ik}}\end{matrix} ] ; {\hat{w}}^{ik} = [ \begin{matrix}0 \\ 0\end{matrix} ] ; {P}_{w}^{ik} = [ \begin{matrix}{\hat{σ}}_{{P}_{e}^{ik}}^{2} & 0 \\ 0 & {\hat{σ}}_{{l}_{m}^{ik}}^{2}\end{matrix} ] & ( 30 )\end{matrix}$$

where P_{\acute{w}}^{ik} and P_{w}^{ik} denote the covariance matrices of \acute{w}^{ik} and w^{ik}, respectively. In order to find the estimates and the variances in equations (27)-(30), the stator voltage, Vⁱ(t), and stator current, Iⁱ(t), measured using VT and CT, respectively, are processed using the DFT method. Thus, \hat{V}ₘ^{ik}, \hat{f}_{V}^{ik}, \hat{θ}_{V}^{ik}, \hat{σ}_{V}_{ₘ}_{^{ik}}², \hat{σ}_{f}_{_{V}}_{^{ik}}² and \hat{σ}_{θ}_{_{V}}_{^{ik}}² are obtained by putting Y(t)=Vⁱ(t) in equations (13)-(22) and updating these estimates and variances for every k^{th} sample. Similarly, Îₘ^{ik}, \hat{f}_{I}^{ik}, \hat{θ}_{I}^{ik}, \hat{σ}_{I}_{ₘ}_{^{ik}}², \hat{σ}_{f}_{_{I}}_{^{ik}}² and \hat{σ}_{θ}_{_{I}}_{^{ik}}² are obtained by putting Y(t)=Iⁱ(t). As \hat{P}ₑ^{ik}=\hat{V}ₘ^{ik}Îₘ^{ik} cos(\hat{θ}_{V}^{ik}−\hat{θ}_{I}^{ik}) (from equation (10)) and the means values and variances of Vₘ^{ik}, Iₘ^{ik}, θ_{V}^{ik}, and θ_{I}^{ik} are known, the mean value of Pₑ^{ik} (denoted as \hat{P}ₑ^{ik}) and its estimated variance (denoted as σ_{P}_{ₑ}_{^{ik}}² can be represented in terms of these known quantities, and have been obtained as follows (here it should be noted that by definition θ_{V}^{ik} and θ_{I}^{ik} lie in the interval (−π/2, π/2], hence, they should be ‘unwrapped’ by adding or subtracting suitable multiples of π to them, in order to find cos(\hat{θ}_{V}^{ik}−\hat{θ}_{I}^{ik}).

$${\hat{P}}_{e}^{ik} = {\hat{V}}_{m}^{ik} {\hat{I}}_{m}^{ik} cos ( {\hat{θ}}_{V}^{ik} - {\hat{θ}}_{I}^{ik} ) \\ {\hat{σ}}_{{P}_{e}^{ik}}^{2} = [ {{\hat{σ}}_{{V}_{m}^{ik}}^{2} ( {\hat{I}}_{m}^{ik} )}^{2} + {( {\hat{V}}_{m}^{ik} )}^{2} {\hat{σ}}_{{I}_{m}^{ik}}^{2} ] {cos}^{2} ( {\hat{θ}}_{V}^{ik} - {\hat{θ}}_{I}^{ik} ) + {( {\hat{V}}_{m}^{ik} )}^{2} {( {\hat{I}}_{m}^{ik} )}^{2} [ {\hat{σ}}_{{θ}_{V}^{ik}}^{2} + {\hat{σ}}_{{θ}_{I}^{ik}}^{2} ] {sin}^{2} ( {\hat{θ}}_{V}^{ik} - {\hat{θ}}_{I}^{ik} ) \qquad ( 31 )$$

Thus, the four quantities which are utilized by the state estimation stage, for example the UKF stage, from the DFT stage are úⁱ, yⁱ, P_{\acute{w}}^{ik}, and P_{w}^{ik}, given by equations (27)-(30). These quantities should be updated ever T₀ s, as this is the sampling period of the UKF stage. Also, in equation (26), both x^{ik} and \acute{w}^{ik} are unknown quantities and may be combined together as a composite state vector X^{ik} with a composite covariance matrix P_{X}^{ik} defined as follows.

$${X}^{ik} = [ \begin{matrix}{x}^{ik} \\ {{w}^{′}}^{ik}\end{matrix} ] ; {\hat{X}}^{ik} = [ \begin{matrix}{\hat{x}}^{ik} \\ {{w}^{{\hat{}}^{′}}}^{ik}\end{matrix} ] ; {P}_{X}^{ik} = [ \begin{matrix}{P}_{x}^{ik} & {P}_{x {w}^{′}}^{ik} \\ {P}_{xw}^{{ik}^{T}} & {P}_{{w}^{′}}^{ik}\end{matrix} ] \qquad ( 32 )$$

Here P_{X}^{ik} is the covariance matrix of x^{ik}, and P_{x\acute{w}}^{ik} is the cross-covariance matrix of x^{ik} and \acute{w}^{ik}. With the above definition, the model in equations (26)-(28) is redefined as follows.

X^{ik}=gⁱ(X^{ik̅},ú^{ik})+v^{ik̅};y^{ik}=hⁱ(X^{ik},ú^{ik})+w^{ik} (33)

With equation (33) as a model and xⁱ⁰ as a steady state estimate of x^{ik} and with the knowledge of gⁱ, hⁱ, úⁱ, yⁱ, P_{\acute{w}}^{ik}, P_{w}^{ik} and the process noise covariance matrix, Pᵥ^{ik}, the filtering equations of the state estimator, for example, the UKF, for the k^{th} iteration of the i^{th} unit are given as follows.

### Operation 1: Initialize

if (k==1) then initialize \hat{x}^{ik̅}=xⁱ⁰, ŵ′^{ik̅}=0_{2X1}, Pₓ^{ik̅}=Pᵥⁱ⁰, Pₓ^{ik̅}=0ₘ_{ⁱ}ₓ₂, P_{w}^{ik̅}=P_{\acute{w}}ⁱ⁰ in equation (32) to get P_{X}^{ik̅} & \hat{X}^{ik̅}.
   else reinitialize ŵ′^{ik} and P_{\acute{w}}^{ik̅}, in equation (32) according to equation (29), leaving the rest of the elements in \hat{X}^{ik̅} and P_{X}^{ik̅} unchanged.

### Operation 2: Generate Sigma Points

$${X}_{l}^{i \overline{k}} = {\hat{X}}^{i \overline{k}} + {( \sqrt{{n}^{i} {P}_{X}^{i \overline{k}}} )}_{l} , l = 1 , 2 , … , {n}^{i} ;$$

$${X}_{l}^{i \overline{k}} = {\hat{X}}^{i \overline{k}} - {( \sqrt{{n}^{i} {P}_{X}^{ik}} )}_{l} , l = ( {n}^{i} + 1 ) , ( {n}^{i} + 2 ) , … 2 {n}^{i} ;$$

### Operation 3: Predict States

$${χ}_{l}^{{ik}^{-}} = {g}^{i} ( {χ}_{l}^{i \overline{k}} , {{u}^{′}}^{i \overline{k}} ) ; {\hat{X}}^{{ik}^{-}} = \frac{1}{2 {n}^{i}} {\sum }_{l = 1}^{2 {n}^{i}} {χ}_{l}^{{ik}^{-}}$$

$${P}_{X}^{{ik}^{-}} = \frac{1}{2 {n}_{i}} {\sum }_{l = 1}^{2 {n}^{-}} {[ {χ}_{l}^{{ik}^{-}} - {\hat{X}}^{{ik}^{-}} ] [ {χ}_{l}^{{ik}^{-}} - {\hat{X}}^{{ik}^{-}} ]}^{T} + {P}_{v}^{ik}$$

### Operation 4: Predict Measurements

$${γ}_{l}^{{ik}^{-}} = {h}^{i} ( {χ}_{l}^{i \overline{k}} , {{u}^{′}}^{i \overline{k}} ) ;$$

$${\hat{y}}^{ik -} = \frac{1}{2 {n}^{i}} {\sum }_{l = 1}^{2 {n}^{i}} {γ}_{l}^{{ik}^{-}} {P}_{y}^{{ik}^{-}} \frac{1}{2 {n}^{i}} {\sum }_{l = 1}^{2 {n}^{i}} {[ {γ}_{l}^{{ik}^{-}} - {\hat{y}}^{{ik}^{-}} ] [ {γ}_{l}^{{ik}^{-}} - {\hat{y}}^{{ik}^{-}} ]}^{T} + {P}_{w}^{ik} {P}_{Xy}^{{ik}^{-}} \frac{1}{2 {n}_{i}} {\sum }_{l = 1}^{2 {n}^{i}} {[ {χ}_{l}^{{ik}^{-}} - {\hat{X}}^{{ik}^{-}} ] [ {γ}_{l}^{{ik}^{-}} - {\hat{y}}^{{ik}^{-}} ]}^{T}$$

### Operation 5: State Estimation Update (e.g., Kalman Update)

K^{ik}=P_{Xy}^{ik-}(P_{y}^{ik-})⁻¹;\hat{X}^{ik}=\hat{X}^{ik-}+K^{ik}(y^{ik}−ŷ^{ik-})

P_{X}^{ik}=P_{X}^{ik̅}−K^{ik}[P_{Xy}^{ik-}]^{T}

### Operation 6: Output and Time Update

output \hat{X}^{ik} and P_{X}^{ik}, k←(k+1), go to Operation 1.

Case Study

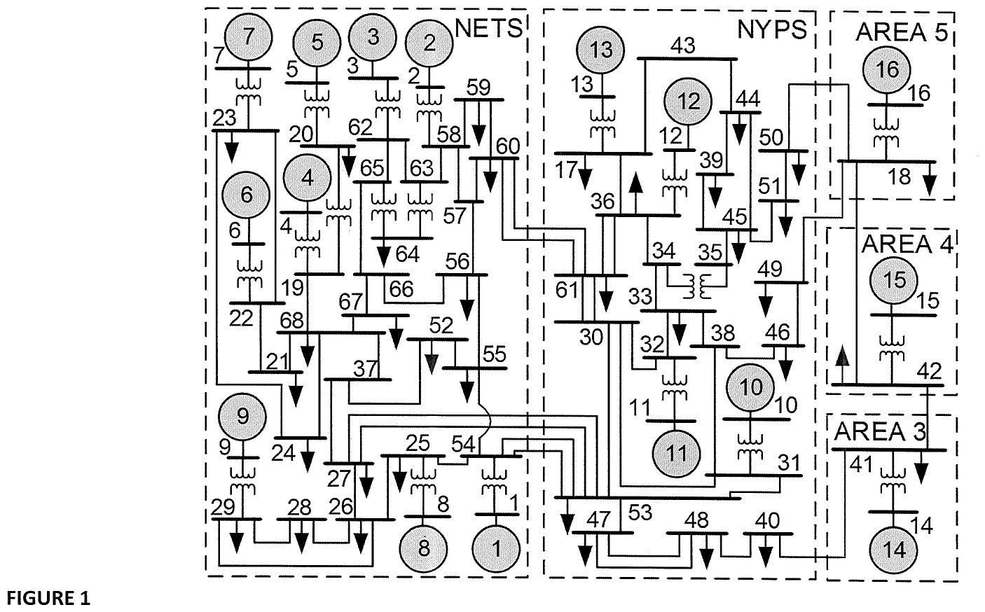

FIG. 1 illustrates a model 16-machine, 68-bus benchmark test system that has been used for the case study presented herein as an example. The test system has been utilized with MATLAB-Simulink running on Windows 7 has been used for its modelling and simulation. A detailed description of the system (including various parameters) is given in B. Pal and B. Chaudhuri, Robust Control in Power Systems. New York, U.S.A.: Springer, 2005; and A. K. Singh, B. C. Pal, “Report on the 68-bus, 16-machine, 5-area system,” IEEE PES Task Force on Benchmark Systems for Stability Controls, version 3.3, pp. 1-41, December 2013. Static AVRs are used in all the machines, and their parameters are given in A. K. Singh, B. C. Pal, “Decentralized Control of Oscillatory Dynamics in Power Systems Using an Extended LQR,” IEEE Trans. Power Syst., vol. 31, no. 3, pp. 1715-1728, May 2016.

According to some of the example embodiments, the robust dynamic state estimator (as discussed under the subheadings ‘Power System Dynamics in a Decoupled Form’ and ‘State Estimation’) runs at the location of each generation unit, and provides dynamic state estimates for the unit. The measurements which are provided to the estimator are V (t) and I(t), and are generated by adding noise to the simulated analogue values of terminal voltage and current of the unit. As explained under the subheading ‘DFT based Estimation’N, f₀ and fₛ are taken as 1200, 50 Hz and 40000 Hz, respectively. The sampling period of state estimation stage (e.g., UKF stage), T₀, is taken as 0.01 s, and thus, the estimates obtained from the DFT stage are also updated every 0.01 s. Also, Pᵥ^{ik} is found. For comparison with the proposed estimator, another UKF based dynamic state estimator which uses PMU measurements also runs at each unit's location and is termed as DSE-with-PMU. Estimate of the internal angle in case of DSE-with-PMU is obtained by subtracting the measurement of terminal voltage phase from the estimate of rotor angle.

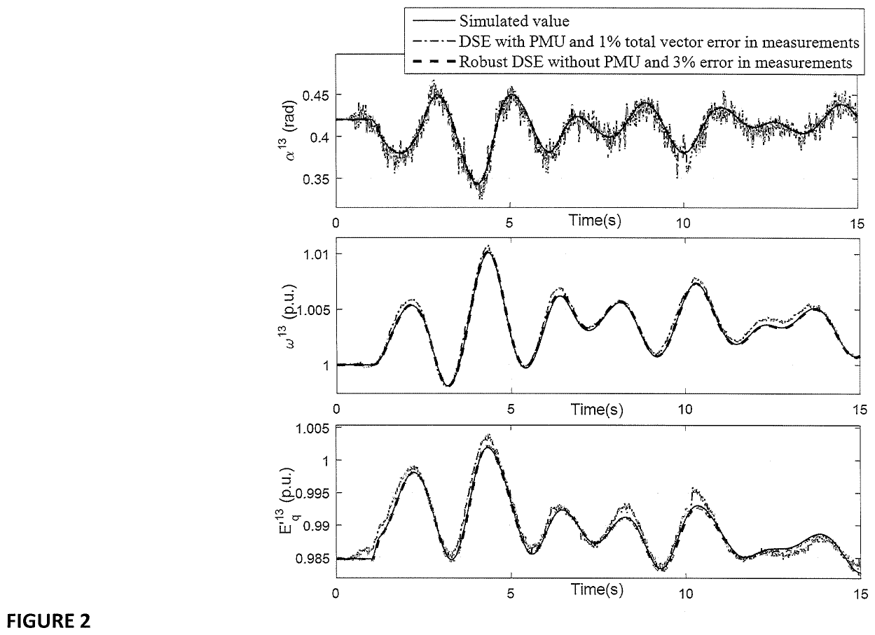

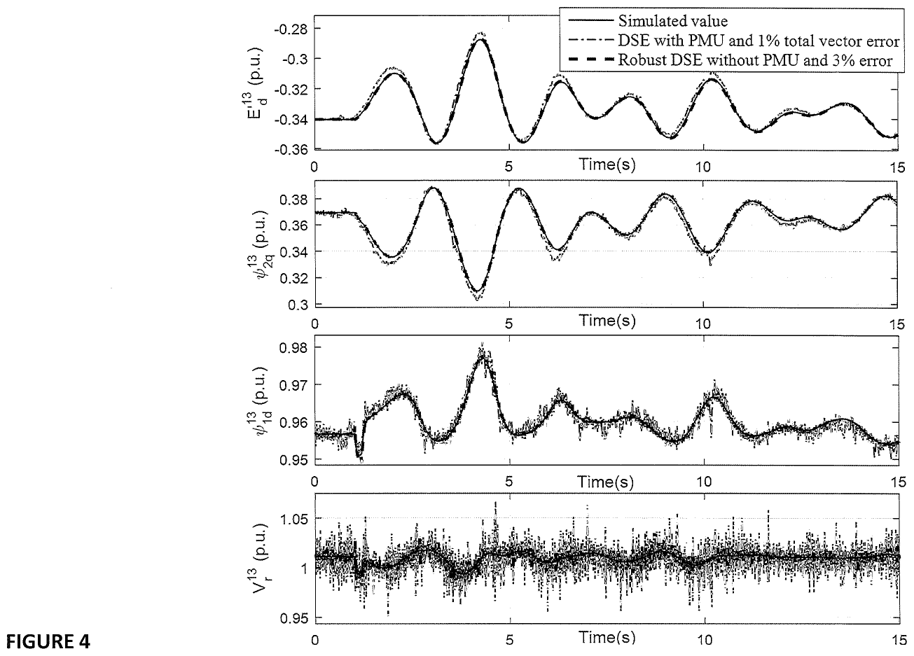

The measurement error for the robust DSE method is the percentage error in the analogue signals of V(t) and I(t), while the measurement error for DSE-with-PMU method is the total vector error (TVE) in the phasor measurements of terminal voltage and current. As the measurement errors for the two estimators are of two different kinds, these methods may not be directly compared for the same noise levels. Nevertheless, performance of the two methods for standard measurement errors can be compared, as specified by IEEE. As mentioned in these standards, the measurement error in CTs/VTs should be less than 3%, while the standard error for PMUs is 1% TVE. Hence, in the base case for comparison, the measurement error for robust DSE is taken as 3%, while for the DSE-with-PMU method, it is taken as 1% TVE. The system starts from a steady state in the simulation. Then at t=1 s, a disturbance is created by a three-phase fault at bus 54 and is cleared after 0.18 s by opening of one of the tie-lines between buses 53-54. The simulated states, along with their estimated values for the base case for one of the units (the 13^{th} unit), have been plotted in FIG. 2 and FIG. 4. Corresponding estimation errors, which is the difference of estimated and simulated values, have also been plotted in

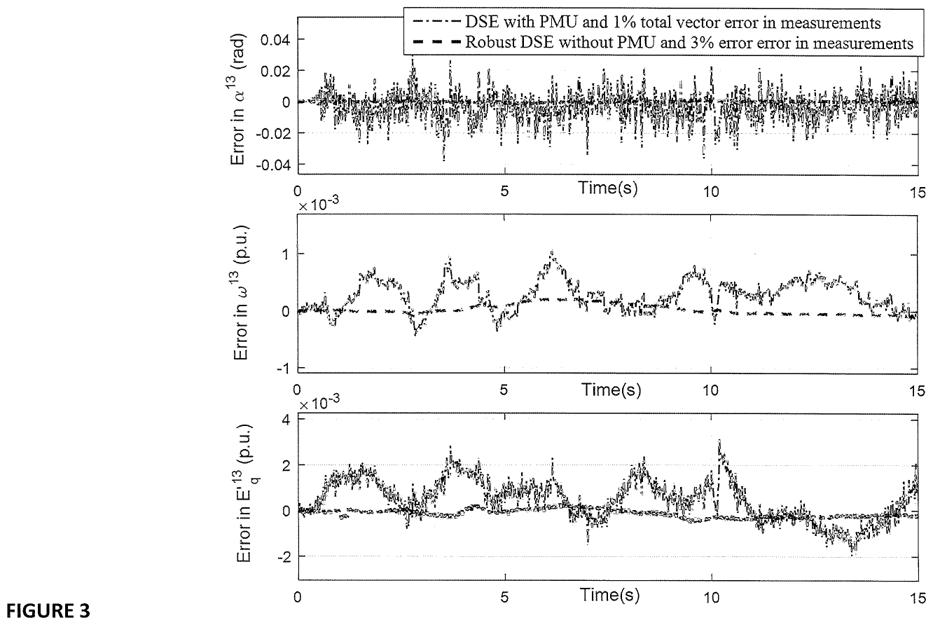

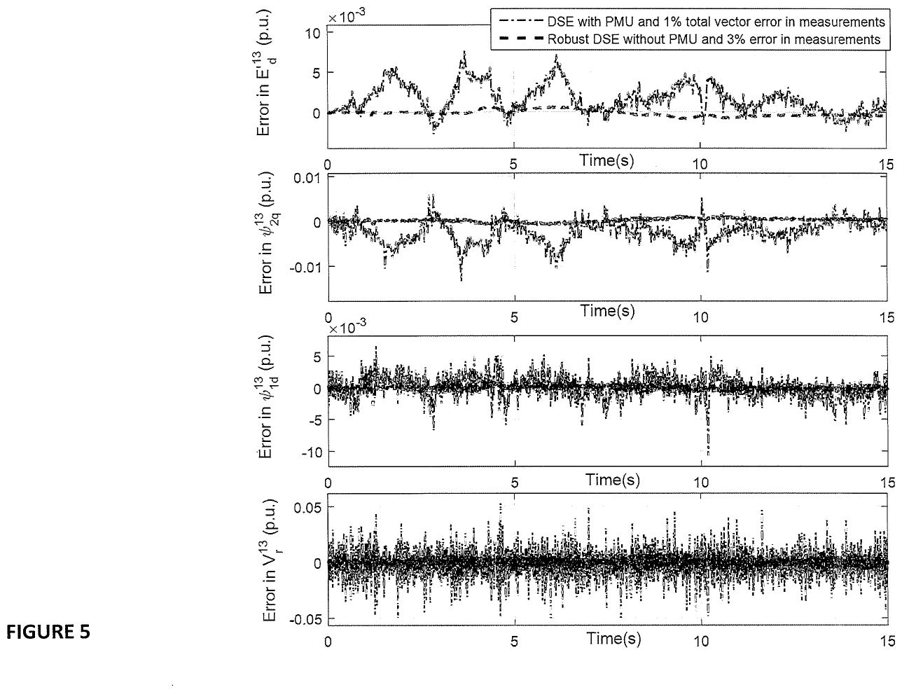

FIG. 3 and FIG. 5.

It can be seen in FIGS. 2-5 that for robust DSE the plots of estimated values almost coincide with those of the simulated values and the estimation errors are low, but for the DSE-with-PMU method the difference between the simulated and estimated values is apparent and the estimation errors are much higher. This shows that the example embodiments perform accurately with standard measurement errors in CTs/VTs, while DSE-with-PMU fails to do so with standard errors in PMU measurements.

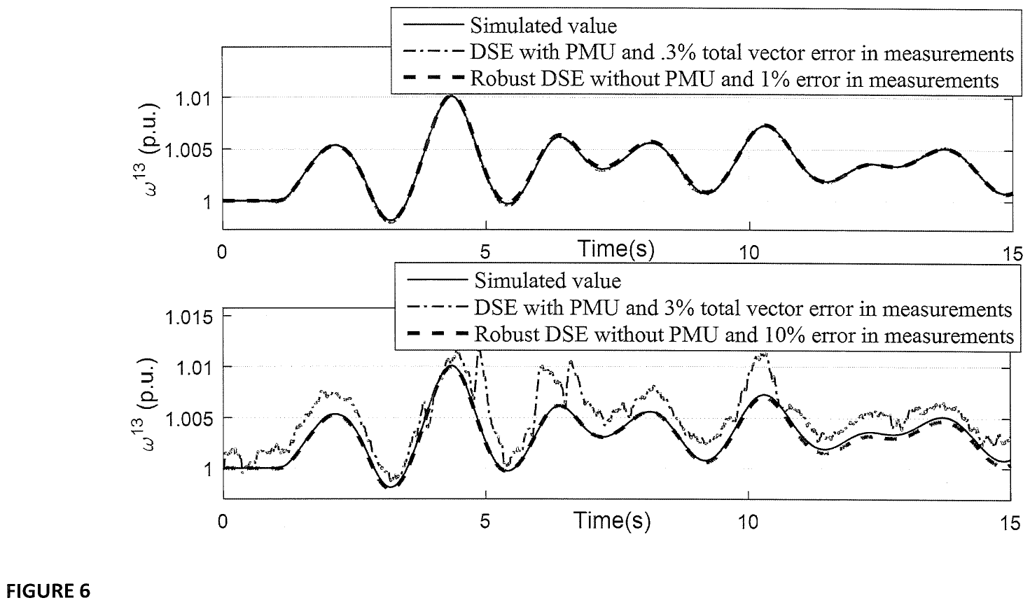

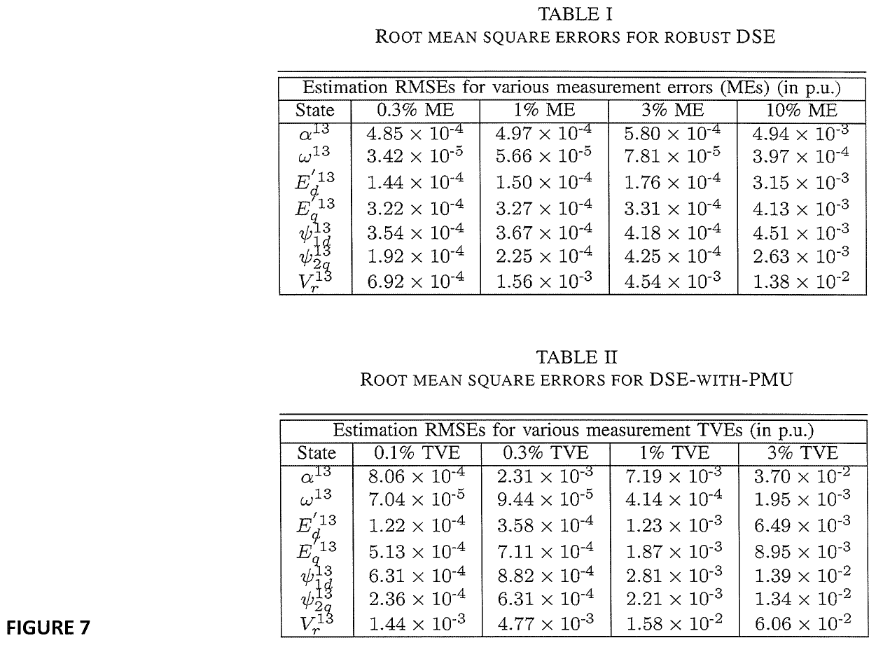

Robustness of the example embodiments has been tested against varying noise levels in measurements. FIG. 6 shows the estimation results for ω¹³ for two more cases: in the first case the noise levels are one-third the base case, while in the second case the noise levels are thrice the base case. Also, root mean squared errors (RMSEs) for varying error levels have been calculated and tabulated in Table I-Table II, which are illustrated in FIG. 7, for the two methods. It can be observed that the performance of the proposed method remains robust to errors up to 3%, and even for 10% error, its performance deteriorates only to a small extent. On the other hand, DSE-with-PMU method does not perform accurately for error levels above 0.3% TVE, that is, it is not accurate for 1% TVE and 3% TVE. It should be noted that various TVE levels have been generated by varying the synchronization errors in the simulated PMU measurements.

Computational feasibility of the example embodiments may be inferred from the fact that the entire simulation, including simulation of the power system, with two estimators at each machine, runs in real-time on MATLAB-Simulink running on Windows 7 on a personal computer with Intel Core 2 Duo, 2.0 GHz CPU and 2 GB RAM. The expression ‘real-time’ here means that 1 second of the simulation takes less than 1 second of processing time. Also, the total execution time for all the operations for the proposed method for one time step (that is for one iteration) is 0.44 millisecond. Thus, the method can be easily implemented using current technologies as the update rate required by the proposed method is 10 milliseconds.

### Example Node Configuration

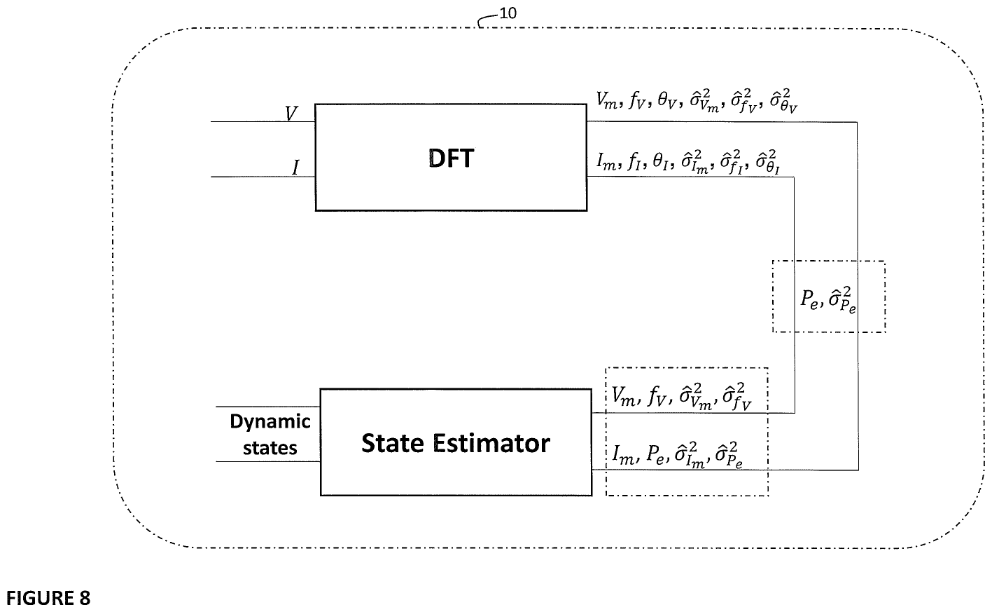

FIG. 8 illustrates a functional example node configuration of an apparatus 10 for DSE of an operational state of a generator in a power system, as described herein. The apparatus 10 may be configured to receive measured voltage (V) and current (I) signals associated with the generator. Upon undergoing signal processing, the signals are input in a Discrete Fourier Transform (DFT). The DFT is used to estimate magnitude, phase and frequency variables of the voltage (Vₘ, θ_{V}, and f_{V}) and current (Iₘ, θ_{I}, and f_{I}), as well as associated voltage and current variances, respectively, for each variable.

The apparatus may be further configured to calculate a power variable (Pₑ), and corresponding power variance, based on the estimated magnitude, phase and frequency variables of the voltage (Vₘ, θ_{V}, and f_{V}) and current (Iₘ, θ_{V}, and f_{I}), as well as associated voltage and current variances, respectively, for each variable.

Thereafter, the dynamic state (DSE) of the generator may be estimated using at least a subset of the estimated magnitude, phase and frequency variables of the voltage (Vₘ, θ_{V}, and f_{V}) and current (Iₘ, θ_{V}, and f_{I}), as well as associated voltage and current variances, respectively, for each variable, as well as the calculated power variable (Pₑ), and corresponding power variance.

In FIG. 8, two examples of such subsets are provided. The first example includes a subset comprising the estimated magnitude of the voltage (Vₘ), the estimated frequency of the voltage (f_{V}), the estimated magnitude of the current (Iₘ) and the calculated power (Pₑ) variable as well as all associated variances. The second example includes a subset comprising the estimated magnitude of the current (Iₘ), the estimated frequency of the current (I_{f}), the estimated magnitude of the voltage (Vₘ) and the calculated power (Pₑ) variable as well as all associated variances.

The chosen subset may thereafter be input in to the state estimator, for example a UKF. The portions of the subset may be provided to the state estimator as differential equations and portions of the subset may be provided to the state estimator as an algebraic equation. The output of the state estimator is the DSE of the operational state of a generator in the power system. According to some of the example embodiments, as the DFT and the state estimator make use of estimated and calculated variances, a more accurate DSE may be provided.

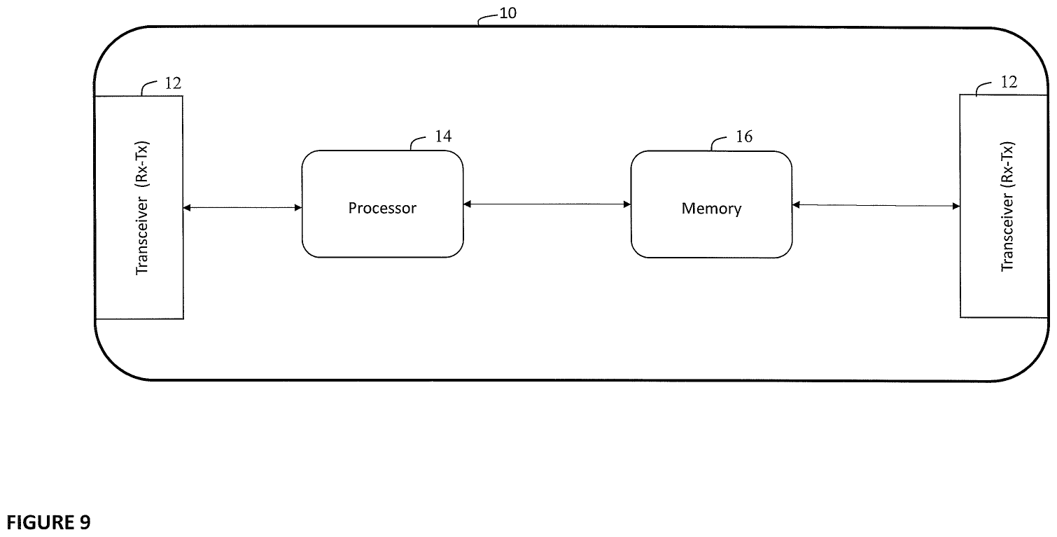

FIG. 9 illustrates an example hardware node configuration of the apparatus 10 of FIG. 8. The apparatus 10 may comprise any number of transceiver 12 which may be configured to receive and transmit any form of measurement, instructions, processing or estimation related information as described herein. According to some of the example embodiments, the transceiver may also comprise a single transceiving interface or any number of receiving and/or transmitting interfaces.

The apparatus 10 of FIG. 9 may also comprise at least one processor 14 which may be configured to process received measurement signals, estimate various variables and variances, calculate a power variable and variance and estimate the DSE of the generator. The processor 14 is further configured to provide an operation discussed herein. The processor 14 may be any suitable computation logic, for example, a microprocessor, digital signal processor (DSP), field programmable gate array (FPGA), or application specific integrated circuitry (ASIC) or any other form of circuitry.

The apparatus 10 may further comprise at least one memory 16 that may be in communication with the transceiver and the processor. The memory 16 may store received or transmitted data, processed data, and/or executable program instructions. The memory may be any suitable type of machine readable medium and may be of a volatile and/or non-volatile type.

### Example Node Operations

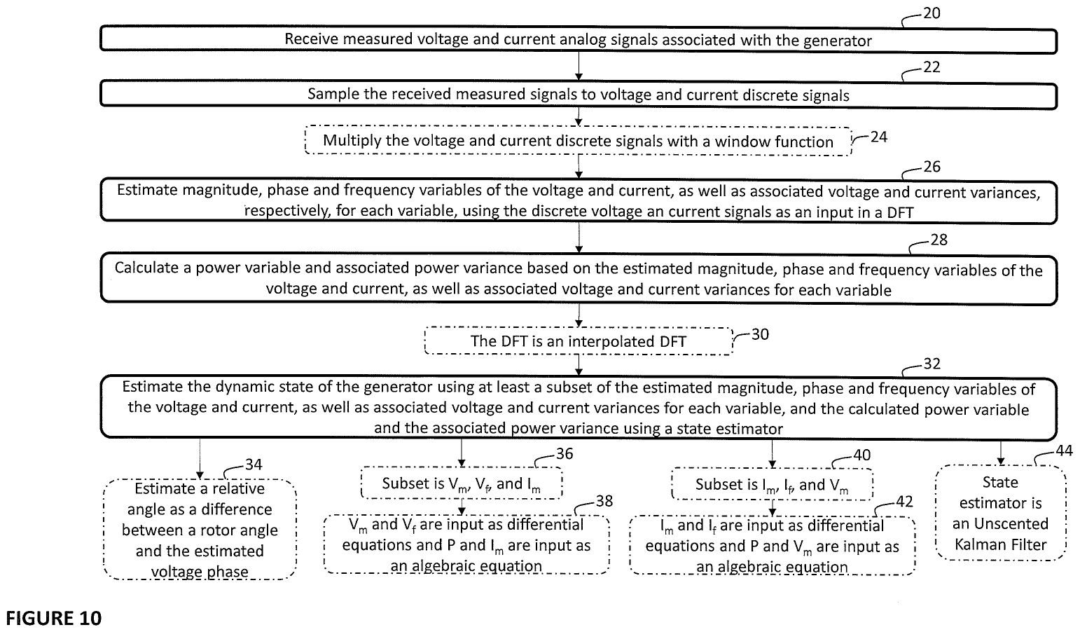

FIG. 10 illustrates a flow diagram depicting example operations which may be taken by the apparatus 10 in Dynamic State Estimation (DSE) of an operational state of a generator in a power system as described herein. It should be appreciated that FIG. 10 comprises some operations which are illustrated in a solid border and some operations which are illustrated with a dashed border. The operations which are comprised in a solid border are operations which are comprised in the broadest aspect. The operations which are comprised in a dashed boarder are example aspects which may be comprised in, or a part of, or are further operations which may be taken in addition to the operations of the broader example aspects. It should be appreciated that these operations need not be performed in order. Furthermore, it should be appreciated that not all the operations need to be performed. The example operations may be performed in any order and in any combination.

Operation 20

The apparatus 10 is to receive 20 measured voltage and current analog signals associated with the generator. The transceiver 12 is to receive measured voltage and current analog signals associated with the generator.

Operation 22

The apparatus 10 is to sample 22 the received measurement signals to voltage and current discrete signals. The processor 14 is to sample the received measurement signals to voltage and current discrete signals.

### Example Operation 24

According to some of the example embodiments, the sampling 22 further comprises multiplying 24 the voltage and current discrete signals with a window function. The processor may multiple the voltage and current discrete signals with the window function.

According to some of the example embodiments, the multiplication with the window function may further comprise a multiplication according to

$$Z ( λ ) = {\sum }_{k = 0}^{N - 1} {Y}_{k} {h}_{k} {e}^{- \frac{j 2 π k λ}{N}} = \frac{{Y}_{m}}{2 j} {e}^{j θ} W ( λ - \frac{fN}{{f}_{s}} ) - \frac{{Y}_{m}}{2 j} {e}^{- j θ} W ( λ + \frac{fN}{{f}_{s}} ) .$$

Example operation 24 is further described under at least the subheading ‘DFT based Estimation’.

Operation 26

The apparatus is further to estimate 26 magnitude, phase and frequency variables of the voltage and current, as well as associated voltage and current variances, respectively, for each variable, using the discrete voltage and current signals as an input in a DFT. The processor 14 is to estimate the magnitude, phase and frequency variables of the voltage and current, as well as associated voltage and current variances, respectively, for each variable, using the discrete voltage and current signals as an input in a DFT.

According to some of the example embodiments, the estimation 26 may be provided according to

$$f = \frac{{f}_{s}}{N} \sqrt{\frac{{Z}_{0} + 2 {Z}_{1} + 9 {Z}_{2}}{{Z}_{0} - 2 {Z}_{1} + {Z}_{2}}} ;$$

$$\frac{{Z}_{0}}{{Z}_{1}} = \frac{{e}^{j \hat{θ}} B + {e}^{- j \hat{θ}} C}{{e}^{j \hat{θ}} E + {e}^{- j {\hat{θ}}_{F}}} ;$$

$$B = \frac{1 - {e}^{\frac{j 2 π \hat{f} N}{{f}_{s}}}}{{\frac{\hat{f} N}{{f}_{s}} [ \frac{\hat{f} N}{{f}_{s}} ]}^{3}} ;$$

$$C = \frac{1 - {e}^{- \frac{j 2 π \hat{f} N}{fs}}}{\frac{\hat{f} N}{{f}_{s}} - {[ \frac{\hat{f} N}{{f}_{s}} ]}^{3}} ;$$

$$E = \frac{1 - {e}^{\frac{j 2 π \hat{f} N}{fs}}}{\frac{\hat{f} N}{{f}_{s}} - 1 - {[ \frac{\hat{f} N}{{f}_{s}} - 1 ]}^{3}} ;$$

$$F = \frac{1 - {e}^{- \frac{j 2 π \hat{f} N}{fs}}}{\frac{\hat{f} N}{{f}_{s}} + 1 - {[ \frac{\hat{f} N}{{f}_{s}} + 1 ]}^{3}} ;$$

$${e}^{j \hat{θ}} = \sqrt{\frac{{Z}_{0} F - {Z}_{1} C}{{Z}_{1} B - {Z}_{0} E}} ⇒ \hat{θ} = \frac{1}{2 j} ln \{ \frac{{Z}_{0} F - {Z}_{1} C}{{Z}_{1} B - {Z}_{0} E} \} ;$$

$${\hat{Y}}_{m} = \frac{8 π {Z}_{0}}{[ N \{ {Be}^{j \hat{θ}} + {Ce}^{- j \hat{θ}} \} ]} ;$$

$$CRB ( \hat{f} ) = {( \frac{fs}{2 π} )}^{2} \frac{24 {σ}_{Y}^{2}}{{\hat{Y}}_{m}^{2} N ( {N}^{2} - 1 )} ;$$

$$CRB ( {\hat{Y}}_{m} ) = \frac{2 {σ}_{Y}^{2}}{N} ;$$

$$CRB ( \hat{θ} ) = \frac{4 {σ}_{Y}^{2} ( 2 N + 1 )}{{\hat{Y}}_{m}^{2} N ( N - 1 )} ;$$

$${\hat{σ}}_{f}^{2} = \frac{2 CRB ( \hat{f} )}{{f}_{o}^{2}} ;$$

$${\hat{σ}}_{{Y}_{m}}^{2} = 2 CRB ( {\hat{Y}}_{m} ) ;$$

$${\hat{σ}}_{θ}^{2} = 6 CRB ( \hat{θ} )$$

An example advantage of operation 26 is that with the calculation of the variances for respective variables, DSE with greater accuracy may be achieved. Operation 26 is further described under at least the subheading ‘DFT based Estimation’.

Operation 28

The apparatus is further to calculate a power variable and associated power variance based on the estimated magnitude, phase and frequency variables of the voltage and current, as well as associated voltage and current variances for each variable. The processor 14 is to calculate the power variable and associated power variance based on the estimated magnitude, phase and frequency variables of the voltage and current, as well as associated voltage and current variances for each variable.

According to some of the example embodiments, the calculated power may be a real power or a reactive power. According to some of the example embodiments, the calculation of the power variable and the associate variance further comprises a calculation according to

$${\hat{P}}_{e}^{ik} = {\hat{V}}_{m}^{ik} {\hat{I}}_{m}^{ik} cos ( {\hat{θ}}_{V}^{ik} - {\hat{θ}}_{I}^{ik} ) ;$$

$${\hat{σ}}_{{P}_{e}^{ik}}^{2} = [ {{\hat{σ}}_{{V}_{m}^{ik}}^{2} ( {\hat{I}}_{m}^{ik} )}^{2} + {( {\hat{V}}_{m}^{ik} )}^{2} {\hat{σ}}_{{I}_{m}^{ik}}^{2} ] {cos}^{2} ( {\hat{θ}}_{V}^{ik} - {\hat{θ}}_{I}^{ik} ) + {( {\hat{V}}_{m}^{ik} )}^{2} {( {\hat{I}}_{m}^{ik} )}^{2} [ {\hat{σ}}_{{θ}_{V}^{ik}}^{2} + {\hat{σ}}_{{θ}_{j}^{ik}}^{2} ] {sin}^{2} ( {\hat{θ}}_{V}^{ik} - {\hat{θ}}_{I}^{ik} ) .$$

Operation 28 is further described under at least the subheading ‘State Estimation’.

### Example Operation 30

According to some of the example embodiments, the DFT is an interpolated DFT. Example operation 30 is further described under at least the subheading ‘DFT based Estimation’.

Operation 32

The apparatus 10 is further to estimate the dynamic state of the generator using at least a subset of the estimated magnitude, phase and frequency variables of the voltage and current, as well as associated voltage and current variances for each variable, and the calculated power variable and the associated power variance using a state estimator. The processor 14 is to estimate the dynamic state of the generator using at least the subset of the estimated magnitude, phase and frequency variables of the voltage and current, as well as associated voltage and current variances for each variable, and the calculated power variable and the associated power variance using the state estimator.

According to some of the example embodiments, the estimating 32 may further comprise estimating the DSE according to

$${{w}^{′}}^{ik} = [ \begin{matrix}{{w}^{′}}_{{V}_{m}^{ik}} \\ {{w}^{′}}_{{f}_{V}^{ik}}\end{matrix} ] ;$$

$${{w}^{{\hat{}}^{′}}}^{ik} = [ \begin{matrix}0 \\ 0\end{matrix} ] ;$$

$${P}_{{w}^{′}}^{ik} = [ \begin{matrix}{\hat{σ}}_{{V}_{m}^{ik}}^{2} & 0 \\ 0 & {\hat{σ}}_{{f}_{V}^{ik}}^{2}\end{matrix} ] ;$$

$${w}^{ik} = [ \begin{matrix}{w}_{{P}_{e}^{ik}} \\ {w}_{{l}_{m}^{ik}}\end{matrix} ] ;$$

$${\hat{w}}^{ik} = [ \begin{matrix}0 \\ 0\end{matrix} ] ;$$

$${P}_{w}^{ik} = [ \begin{matrix}{\hat{σ}}_{{P}_{e}^{ik}}^{2} & 0 \\ 0 & {\hat{σ}}_{{I}_{m}^{ik}}^{2}\end{matrix} ] ;$$

$${\hat{P}}_{e}^{ik} = {\hat{V}}_{m}^{ik} {\hat{I}}_{m}^{ik} cos ( {\hat{θ}}_{V}^{ik} - {\hat{θ}}_{I}^{ik} ) ;$$

$${\hat{σ}}_{{P}_{e}^{ik}}^{2} = [ {{\hat{σ}}_{{V}_{m}^{ik}} ( {\hat{I}}_{m}^{ik} )}^{2} + {( {\hat{V}}_{m}^{ik} )}^{2} {\hat{σ}}_{{I}_{m}^{ik}}^{2} ] {cos}^{2} ( {\hat{θ}}_{V}^{ik} - {\hat{θ}}_{I}^{ik} ) + {( {\hat{V}}_{m}^{ik} )}^{2} {( {\hat{I}}_{m}^{ik} )}^{2} [ {\hat{σ}}_{{θ}_{V}^{ik}}^{2} + {\hat{σ}}_{{θ}_{I}^{ik}}^{2} ] {sin}^{2} ( {\hat{θ}}_{V}^{ik} - {\hat{θ}}_{I}^{ik} ) ;$$

$${X}^{ik} = [ \begin{matrix}{x}^{ik} \\ {{w}^{′}}^{ik}\end{matrix} ] ;$$

$${\hat{X}}^{ik} = [ \begin{matrix}{\hat{x}}^{ik} \\ {{w}^{{\hat{}}^{′}}}^{ik}\end{matrix} ] ;$$

$${P}_{X}^{ik} = [ \begin{matrix}{P}_{x}^{ik} & {P}_{{xw}^{′}}^{ik} \\ {P}_{{xw}^{′}}^{{ik}^{T}} & {P}_{{w}^{′}}^{ik}\end{matrix} ] ;$$

$${X}^{ik} = {g}^{i} ( {X}^{i \overline{k}} , {u}^{i \overline{k}} ) + {v}^{i \overline{k}} ;$$

$${y}^{ik} = {h}^{i} ( {X}^{ik} , {{u}^{′}}^{ik} ) + {w}^{ik} .$$

### Example Operation 34

According to some of the example embodiments, the estimating 32 of the dynamic state is based on, at least in part, estimating 34 a relative angle as a difference between a rotor angle and the estimated voltage phase. The processor 14 may estimate the relative angle as the difference between the rotor angle and the estimated voltage phase.

According to some of the example embodiments, the estimating of the relative angle further comprises estimating the relative angle according to Δ\dot{α}ⁱ=(ωⁱ−f_{V}ⁱ). An example advantage of example operation 34 is that with the use of a relative angle, time synchronization may be avoided. Example operation 34 is further described under at least the subheading ‘Power System Dynamics in a Decoupled Form’.

### Example Operation 36

According to some of the example embodiments, the estimating 32 is based on a subset of the estimated magnitude of the voltage, the estimated frequency of the voltage and the estimated magnitude of the current. The processor 14 may base the estimation of the dynamic states on a subset comprising the estimated magnitude of the voltage, the estimated frequency of the voltage and the estimated magnitude of the current.

### Example Operation 38

According to the embodiments in which the subset is as described in example operation 36, the estimated magnitude of the voltage and the estimated frequency of the voltage and associated voltage variances are inputs to the state estimator, and are utilized as pseudo-inputs, and are provided in differential equations of the state estimator, and the estimated magnitude of the current and the calculated power and associated current and power variances are provided as an algebraic equation and are given as measurement inputs to the state estimator.

According to such example embodiments, the differential equations are represented as x^{ik}=x^{ik̅}+T₀ǵ^{l}(x^{ik̅}, ú^{ik̅}, \acute{w}^{ik̅})+v^{ik̅}⇒x^{ik}=gⁱ(x^{ik̅}, u^{ik̅}, \acute{w}^{ik̅})+v^{ik̅}, where x is a column vector of a state, k̅=(k−1), T₀ is a sampling period in seconds, g is a discrete form of a differential function, u is a column vector of pseudo-inputs, w is a column vector of noise, i is the i^{th} generation unit, and k is the k^{th} sample and the algebraic equation is represented as

$${y}^{ik} = [ \begin{matrix}{\hat{P}}_{e}^{ik} \\ {\hat{I}}_{m}^{ik}\end{matrix} ] = [ \begin{matrix}{V}_{d}^{ik} {I}_{d}^{ik} + {V}_{q}^{ik} {I}_{q}^{ik} \\ \sqrt{{I}_{d}^{{ik}^{2}} + {I}_{q}^{{ik}^{2}}}\end{matrix} ] + {w}^{ik} ⇒ {y}^{ik} = {h}^{i} ( {x}^{ik} , {{u}^{′}}^{ik} , {{w}^{′}}^{ik} ) + {w}^{ik} .$$

Example operation 38 is further described under at least subheading ‘State Estimation’.

### Example Operation 40

According to some of the example embodiments, the estimating 32 is based on a subset of the estimated magnitude of the current, the estimated frequency of the current and the estimated magnitude of the voltage. The processor 14 is to estimate the dynamic state based on the subset of the estimated magnitude of the current, the estimated frequency of the current and the estimated magnitude of the voltage.

### Example Operation 42

According to the embodiments in which the subset is as described in example operation 40, the estimated magnitude of the current and the estimated frequency of the current and associated current variances are inputs to the state estimator and are used in differential equations of the state estimator, and the estimated magnitude of the voltage and the calculated power and associated voltage and power variances are represented as an algebraic equation and is given as a measurement input to the state estimator.

It should further be appreciated that other such subsets may be utilized. For example, according to some of the example embodiments, the subset of the estimated magnitude, phase and frequency variables of the voltage and current is the estimated magnitude of the voltage, the estimated magnitude of the current and the estimated frequency of the voltage. According to such embodiments, the estimated magnitude of the voltage and the estimated magnitude of the current and associated voltage and current variances are inputs to the state estimator and are used in differential equations of the state estimator, and the estimated frequency of the voltage and the calculated power and associated voltage and power variances are represented as an algebraic equation and is given as a measurement input to the state estimator, wherein the calculated power is reactive power.

According to some of the example embodiments, the subset of the estimated magnitude, phase and frequency variables of the voltage and current is the estimated magnitude of the current, the estimated frequency of the current and the estimated magnitude of the voltage. According to such example embodiments, the estimated magnitude of the current and the estimated frequency of the current and associated current variances are inputs to the state estimator and are used in differential equations of the state estimator, and the estimated magnitude of the voltage and the calculated power and associated voltage and power variances are represented as an algebraic equation and is given as a measurement input to the state estimator. Example operation 42 is further described under at least subheading ‘State Estimation’.

### Example Operation 44

According to some of the example embodiments, the estimating 32 further comprises estimating the DSE with the use of a UKF as the state estimator. The processor 14 may estimate the DSE with the use of the UKF as the state estimator.

The various example embodiments described herein are described in the general context of method steps or processes, which may be implemented in one aspect by a computer program product, embodied in a computer-readable medium, comprising computer-executable instructions, such as program code, executed by computers in networked environments. A computer-readable medium may comprise removable and non-removable storage devices comprising, but not limited to, Read Only Memory (ROM), Random Access Memory (RAM), compact discs (CDs), digital versatile discs (DVD), etc. Generally, program modules may comprise routines, programs, objects, components, data structures, etc. that perform particular tasks or implement particular abstract data types. Computer-executable instructions, associated data structures, and program modules represent examples of corresponding acts for implementing the functions described in such steps or processes.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The example embodiments not restricted to the details of any foregoing embodiments. The example embodiments extend to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

In the drawings and specification, there have been disclosed exemplary embodiments. However, many variations and modifications may be made to these embodiments. Accordingly, although specific terms are employed, they are used in a generic and descriptive sense only and not for purposes of limitation, the scope of the embodiments being defined by the following claims.

1-61. (canceled)

62. A method for Dynamic State Estimation, DSE, of an operational state of a generator in a power system, the method comprising:
receiving measured voltage and current analog signals associated with the generator;
sampling the received measured signals to voltage and current discrete signals;
estimating magnitude, phase and frequency variables of the voltage and current, as well as associated voltage and current variances, respectively, for each variable, using the discrete voltage and current signals as an input in a Discrete Fourier Transform, DFT;
calculating a power variable and associated power variance based on the estimated magnitude, phase and frequency variables of the voltage and current, as well as associated voltage and current variances for each variable; and
estimating the dynamic state of the generator using at least a subset of the estimated magnitude, phase and frequency variables of the voltage and current, as well as associated voltage and current variances for each variable, and the calculated power variable and the associated power variance using a state estimator.

63. The method of claim 62, wherein the estimating the dynamic state of the generator is based on, at least in part, estimating a relative angle as a difference between a rotor angle and the estimated voltage phase.

64. The method of claim 63, wherein the estimating the relative angle further comprises estimating the relative angle according to Δ\dot{α}ⁱ=(ωⁱ−f_{V}ⁱ), where α is the difference between the rotor angle and the estimated voltage phase, co is rotor speed and f_{V} is the frequency variable of the voltage of the i^{th} generator.

65. The method of claim 62, wherein the sampling further comprises multiplying the voltage and current discrete signals with a window function.

66. The method of claim 65, wherein the multiplying with the window function further comprises multiplying according to
$$Z ( λ ) = {\sum }_{k = 0}^{N - 1} {Y}_{k} {h}_{k} {e}^{- \frac{j 2 π k λ}{N}} = \frac{{Y}_{m}}{2 j} {e}^{j θ} W ( λ - \frac{fN}{{f}_{s}} ) - {e}^{- j θ} W ( λ + \frac{fN}{{f}_{s}} ) ,$$
where Z is a DFT of a product of Y and h, N denotes total number of samples for fining the DFT, k denotes a discrete sample, Y denotes a sinusoidal signal with harmonics and noise, h is a window function, W is a DFT of the window function, f is the frequency of Y's fundamental component in Hz, fₛ is a sampling frequency for DFT in Hz, and λ∈{0, 1, . . . , (N−1)}.

67. The method according to claim 62, wherein the subset of the estimated magnitude, phase and frequency variables of the voltage and current is the estimated magnitude of the voltage, the estimated frequency of the voltage and the estimated magnitude of the current.

68. The method according to claim 67, wherein the estimated magnitude of the voltage and the estimated frequency of the voltage and associated voltage variances are inputs to the state estimator, and are utilized as pseudo-inputs, and are provided in differential equations of the state estimator, and the estimated magnitude of the current and the calculated power and associated current and power variances are provided as an algebraic equation and are given as measurement inputs to the state estimator.

69. The method according to claim 68, wherein the differential equations are represented as x^{ik}=x^{ik̅}+T₀ǵ^{l}(x^{ik̅}, ú^{ik̅}, \acute{w}^{ik̅})+v^{ik̅}⇒x^{ik}=gⁱ(x^{ik̅}, u^{ik̅}, \acute{w}^{ik̅})+v^{ik̅}, where x is a column vector of a state, k̅=(k−1), T₀ is a sampling period in seconds, g is a discrete form of a differential function, u is a column vector of pseudo-inputs, w is a column vector of noise, i is the i^{th} generation unit, and k is the k^{th} sample and the algebraic equation is represented as
$${y}^{ik} = [ \begin{matrix}{\hat{P}}_{e}^{ik} \\ {\hat{I}}_{m}^{ik}\end{matrix} ] = [ \begin{matrix}{V}_{d}^{ik} {I}_{d}^{ik} + {V}_{q}^{ik} {I}_{q}^{ik} \\ \sqrt{{I}_{d}^{{ik}^{2}} + {I}_{q}^{{ik}^{2}}}\end{matrix} ] + {w}^{ik} ⇒ {y}^{ik} = {h}^{i} ( {x}^{ik} , {{u}^{′}}^{ik} , {{w}^{′}}^{ik} ) + {w}^{ik} ,$$
where y is a column vector of a measurement, Pₑ denotes active electrical-power output of a machine, I and Iₘ represents an analogue stator current and its magnitude, respectively, V_{d} and V_{q} represents d-axis and q-axis stator voltages, respectively, I_{d} and I_{q} represents d-axis and q-axis stator currents, respectively.

70. The method according to claim 62, wherein the subset of the estimated magnitude, phase and frequency variables of the voltage and current is the estimated magnitude of the current, the estimated frequency of the current and the estimated magnitude of the voltage.

71. The method according to claim 70, wherein the estimated magnitude of the current and the estimated frequency of the current and associated current variances are inputs to the state estimator and are used in differential equations of the state estimator, and the estimated magnitude of the voltage and the calculated power and associated voltage and power variances are represented as an algebraic equation and is given as a measurement input to the state estimator.

72. The method according to claim 62, wherein the subset of the estimated magnitude, phase and frequency variables of the voltage and current is the estimated magnitude of the voltage, the estimated magnitude of the current and the estimated frequency of the voltage.

73. The method according to claim 72, wherein the estimated magnitude of the voltage and the estimated magnitude of the current and associated voltage and current variances are inputs to the state estimator and are used in differential equations of the state estimator, and the estimated frequency of the voltage and the calculated power and associated voltage and power variances are represented as an algebraic equation and is given as a measurement input to the state estimator, wherein the calculated power is reactive power.

74. The method according to claim 62, wherein the subset of the estimated magnitude, phase and frequency variables of the voltage and current is the estimated magnitude of the current, the estimated frequency of the current and the estimated magnitude of the voltage.

75. The method according to claim 74, wherein the estimated magnitude of the current and the estimated frequency of the current and associated current variances are inputs to the state estimator and are used in differential equations of the state estimator, and the estimated magnitude of the voltage and the calculated power and associated voltage and power variances are represented as an algebraic equation and is given as a measurement input to the state estimator.

76. The method according to claim 62, wherein the calculated power is real power or reactive power of the generator.

77. The method according to claim 62, wherein the estimation of the magnitude, phase and frequency variables of the voltage and current, as well as associated variance for each variable further comprises estimating according to
$$\hat{f} = \frac{{f}_{s}}{N} \sqrt{\frac{{Z}_{0} + 2 {Z}_{1} + 0 {Z}_{2}}{{Z}_{0} - 2 {Z}_{1} + {Z}_{2}}} , \\ \frac{{Z}_{0}}{{Z}_{1}} = \frac{{e}^{j \hat{θ}} B + {e}^{- j \hat{θ}} C}{{e}^{j θ} E + {e}^{j \hat{θ}} F} ;$$
$$B = \frac{1 - {e}^{\frac{j 2 π \hat{f} N}{fs}}}{\frac{\hat{f} N}{{f}_{s}} - {[ \frac{\hat{f} N}{{f}_{s}} ]}^{3}} ;$$
$$C = \frac{1 - {e}^{\frac{j 2 π \hat{f} N}{{f}_{s}}}}{\frac{\hat{f} N}{fs} - {[ \frac{\hat{f} N}{fs} ]}^{3}} ;$$
$$E = \frac{1 - {e}^{\frac{j 2 π \hat{f} N}{fs}}}{\frac{\hat{f} N}{{f}_{s}} - 1 - {[ \frac{\hat{f} N}{{f}_{s}} - 1 ]}^{3}} ;$$
$$F = \frac{1 - {e}^{\frac{j 2 π \hat{f} N}{fs}}}{\frac{\hat{f} N}{{f}_{s}} + 1 - {[ \frac{\hat{f} N}{{f}_{s}} + 1 ]}^{3}} ;$$
$${e}^{j \hat{θ}} = \sqrt{\frac{{Z}_{0} F - {Z}_{1} C}{{Z}_{1} B - {Z}_{0} E}} ⇒ \hat{θ} = \frac{1}{2 j} ln \{ \frac{{Z}_{0} F - {Z}_{1} C}{{Z}_{1} B - {Z}_{0} E} \} ;$$
$${\hat{Y}}_{m} = \frac{8 π {Z}_{0}}{[ N \{ {Be}^{j \hat{θ}} + {Ce}^{- j \hat{θ}} \} ]} ;$$
$$CRB ( \hat{f} ) = {( \frac{fs}{2 π} )}^{2} \frac{24 {σ}_{Y}^{2}}{{\hat{Y}}_{m}^{2} N ( {N}^{2} - 1 )} ;$$
$$CRB ( {\hat{Y}}_{m} ) = \frac{2 {σ}_{Y}^{2}}{N} ;$$
$$CRB ( \hat{θ} ) = \frac{4 {σ}_{Y}^{2} ( 2 N + 1 )}{{\hat{Y}}_{m}^{2} N ( N - 1 )} ;$$
$${\hat{σ}}_{f}^{2} = \frac{2 CRB ( \hat{f} )}{{f}_{0}^{2}} ;$$
$${\hat{σ}}_{{Y}_{m}}^{2} = 2 CRB ( {\hat{Y}}_{m} ) ;$$
$${\hat{σ}}_{θ}^{2} = 6 CRB ( \hat{θ} ) ,$$
where Y denotes a sinusoidal signal with harmonics and noise, h is a window function, Z is a DFT of the product of Y and h, f is a frequency of Y's fundamental component in Hz, Yₘ is a magnitude of Y's fundamental component, fₛ is a sampling frequency for DFT in Hz, N is a total number of samples for finding DFT, CRB is a Cramer-Rao bound, a denotes standard deviation with σ² as its variance, θ denotes a phase in Y's fundamental component, and f₀ denotes a voltage base value in Hz.

78. The method according to claim 62, wherein the DFT is an interpolated DFT.

79. The method according to claim 62, wherein the state estimator is an Unscented Kalman filter, UKF.

80. An apparatus for Dynamic State Estimation, DSE, of an operational state of a generator in a power system, the apparatus comprising:
a transceiver to receive measured voltage and current analog signals associated with the generator;
a processor to sample the received measured signals to voltage and current discrete signals;
the processor to estimate magnitude, phase and frequency variables of the voltage and current, as well as associated voltage and current variances, respectively, for each variable, using the discrete voltage and current signals as an input in a Discrete Fourier Transform, DFT;
the processor to calculate a power variable and associated power variance based on the estimated magnitude, phase and frequency variables of the voltage and current, as well as associated voltage and current variances for each variable; and
the processor to estimate the dynamic state of the generator using at least a subset of the estimated magnitude, phase and frequency variables of the voltage and current, as well as associated voltage and current variances for each variable, and the calculated power variable and the associate power variance using a state estimator.

81. A computer readable medium having executable instructions stored thereon which, when executed by an apparatus for Dynamic State Estimation, DSE, of an operational state of a generator in a power system, cause the apparatus to:
receive measured voltage and current analog signals associated with the generator;
sample the received measured signals to voltage and current discrete signals;
estimate magnitude, phase and frequency variables of the voltage and current, as well as associated voltage and current variances, respectively, for each variable, using the discrete voltage and current signals as an input in a Discrete Fourier Transform, DFT;
calculate a power variable and associated power variance based on the estimated magnitude, phase and frequency variables of the voltage and current, as well as associated voltage and current variances for each variable; and
estimate the dynamic state of the generator using at least a subset of the estimated magnitude, phase and frequency variables of the voltage and current, as well as associated voltage and current variances for each variable, and the calculated power variable and the associate power variance using a state estimator.
